(19) United States
(12) Patent Application Publication
(10) Pub. No.: US 2024/0377816 A1
(43) Pub. Date: Nov. 14, 2024

(54) GENERATING MODELS FOR MULTIPHYSICS SYSTEMS USING DESIGN INFORMATION

(71) Applicant: Rockwell Automation Technologies, Inc., Mayfield Heights, OH (US)

(72) Inventors: Michael D. Cook, Mequon, WI (US); Alexander G. Brynildsen, Milwaukee, WI (US)

(21) Appl. No.: 18/316,647

(22) Filed: May 12, 2023

(51) Int. Cl. G05B 19/418

(52) U.S. Cl. CPC G05B 19/41835; G05B 2219/31368

(57) ABSTRACT

A method includes receiving, via one or more processors, design information indicating an arrangement of a plurality of industrial automation components, wherein the plurality of industrial automation components comprises a motor. The method also includes determining, via the one or more processors, an equation of motion representing a mechanical operation of the plurality of industrial automation components based on the arrangement of the plurality of industrial automation components. Further, the method includes determining, via the one or more processors, a plurality of mechanical parameters representing the mechanical operation of the plurality of industrial automation components based on the equation of motion. Further still, the method includes generating, via the one or more processors, a model of the plurality of industrial automation components based on the plurality of mechanical parameters, wherein model represents one or more operations of a physical arrangement of the plurality of industrial automation components.

### BACKGROUND

The present disclosure generally relates to control systems and, more particularly, to control systems using design information and/or drive data and determining experimental operations based on process data for monitoring, diagnostics, control, and optimization of processes.

Generally, a control system may facilitate performance of an industrial automation process by controlling operations of one or more automation devices. For example, to facilitate performing an industrial automation process, the control system may determine a control action and instruct an automation device (e.g., a rod-pump) to perform the control action. Additionally, the control system may facilitate monitoring performance of the process to determine whether the process is operating as desired. When not operating as desired, the control system may also facilitate performing diagnostics on the process to determine a cause of undesired operation.

It may be desirable to utilize a model predictive control (MPC) system to optimize performance of the process. However, generating a process model to control the process is difficult and a user that utilizes the process model may not have access to resources and/or sufficient technical expertise to generate the process model themselves. As such, it may be desirable to provide improved systems and methods for creating or generating a process model to enable users to implement process models. For example, it may be desirable to provide techniques that enable the user to create or generate a model using information that is available to the user.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as admissions of prior art.

### BRIEF DESCRIPTION OF DRAWINGS

These and other features, aspects, and advantages of the present disclosure will become better understood when the following detailed description is read with reference to the accompanying drawings in which like characters represent like parts throughout the drawings, wherein:

FIG. 1 illustrates an example industrial automation system employed by a food manufacturer, in accordance with an embodiment;

FIG. 2 illustrates a diagrammatical representation of an exemplary control and monitoring system that may be employed in any suitable industrial automation system, in accordance with an embodiment;

FIG. 3 illustrates example components that may be part of a control/monitoring device that may be implemented in the industrial automation system, in accordance with an embodiment;

FIG. 4 illustrates a mechanical load identification system that may be implemented in the control/monitoring device, in accordance with an embodiment;

FIG. 5 is a flow diagram of an embodiment for adjusting operation of one or more industrial automation components based on design information and a motion profile of the one or more industrial automation components, in accordance with an embodiment;

FIG. 6 is a flow diagram of an embodiment for generating a model representative of one or more industrial automation components based on design information and a motion profile of the one or more industrial automation components, in accordance with an embodiment; and

FIG. 7 is a flow diagram of an embodiment for performing one or more tests to determine mechanical parameters associated with one or more industrial automation components, in accordance with an embodiment.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, the present disclosure relates to a method. The method includes receiving, via one or more processors, design information indicating an arrangement of a plurality of industrial automation components, wherein the plurality of industrial automation components comprises a motor. The method also includes determining, via the one or more processors, an equation of motion representing a mechanical operation of the plurality of industrial automation components based on the arrangement of the plurality of industrial automation components. Further, the method includes determining, via the one or more processors, a plurality of mechanical parameters representing the mechanical operation of the plurality of industrial automation components based on the equation of motion. Further still, the method includes generating, via the one or more processors, a model of the plurality of industrial automation components based on the plurality of mechanical parameters, wherein model represents one or more operations of a physical arrangement of the plurality of industrial automation components.

In another embodiment, the present disclosure relates to a method. The method includes receiving, via one or more processors, drive data corresponding to a load provided by a motor to one or more industrial automation components. The method also includes adjusting, via the one or more processors, a mechanical operation of the one or more industrial automation components via the motor. Further, the method includes determining, via the one or more processors, a plurality of mechanical parameters of the one or more industrial automation components based on a change of the drive data resulting from the adjusted mechanical operation. Further still, the method includes generating, via the one or more processors, a model representative of the one or more industrial automation components based on the plurality of mechanical parameters.

In yet another embodiment, the present disclosure relates to a non-transitory computer-readable medium comprising computer-executable instructions that, when executed, are configured to cause a processor to perform operations including receiving drive data corresponding to a load provided to one or more of industrial automation components by a motor. The operations also include adjusting a mechanical operation of the one or more industrial automation components via the motor in accordance with a plurality of tests. Further, the operations include determining, via the one or more processors, a plurality of mechanical parameters of an equation of motion representing movement by the one or more industrial automation components with respect to the motor based on the plurality of tests. Further still, the operations include generating, via the one or more processors, a model representative of the equation of motion of the one or more industrial automation components based on the plurality of mechanical parameters.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” “the,” and “said” are intended to mean that there are one or more of the elements. The terms “comprising,” “including,” and “having” are intended to be inclusive and mean that there may be additional elements other than the listed elements.

As described above, it may be advantageous to provide systems and methods that generate a model used in an industrial automation system (e.g., a process model, a discrete model, or a hybrid model) using information or data that is available to the user because the user may not have a sufficient expertise for generating a new model and/or it may otherwise be inefficient for the user to generate the model. For example, an industrial automation process may include industrial automation components, equipment, or machines that include sub components (e.g., industrial automation subcomponents) that operate cooperatively to perform a desired task, such as moving goods, applying a torque to a machine, and the like. The subcomponents may include motors, a drive, gear trains, or other machine equipment. The user may have access to the physical industrial automation components (e.g. the physical components and the industrial automation components), but without a model, it may be difficult for the user to determine how to optimize performance of the physical system. For example, it may be difficult for a user to determine how a particular design a layout or arrangement for the industrial automation components may accomplish the desired task in a suitable matter (e.g., at a particular throughput or efficiency). As such, it may be desirable to provide improved systems and methods for generating the process model, the discrete model, or hybrid model using data that is more easily obtainable by a user.

With this in mind, the present disclosure is directed to a mechanical load identification system. In general, the mechanical load identification system utilizes design information and/or drive data (e.g., drive data) of industrial automation components to generate a model representing a physical industrial automation component. As used herein, “drive data” may include data indicating a load provided by mechanical devices (e.g., motors) used to control operation of other industrial automation components. For example, the mechanical load identification system may execute multiple tests that adjust physical operations of the physical industrial automation components (e.g., cause the physical industrial automation components to operate at a constant velocity, constant acceleration, or a hold a particular position for a predetermined amount of time) to determine a virtual model representing the physical industrial automation component. The mechanical load identification system may measure the drive data used to drive a motor that drives the physical operations. The drive data may be used to determine mechanical parameters (e.g., a torque, acceleration inertia coefficients, viscous friction coefficients, Coriolis coefficients, other mechanical parameters related to the mechanical operation of the industrial automation components) of the physical industrial automation components. In turn, the mechanical load identification system may generate a mechanical load output that includes a model, such as a digital twin of the physical industrial automation component and/or a motion profile corresponding to the physical industrial automation component, and/or a bill of materials (BOM) for the physical industrial automation component.

Additionally or alternatively, the mechanical load identification system may utilize design information to generate the mechanical load output. As used herein, “design information” may include a computer-aided design (CAD) file or other documentation including information such as physical dimensions of one or more subcomponents of the industrial automation component. For example, the mechanical load identification system may identify an arrangement of multiple industrial automation components and/or subcomponents using the design information, where at least one is capable of providing motion to the other industrial automation components, such as a motor. As such, the mechanical load identification system may determine a virtual representation of the physical system that indicates how the industrial automation components operate cooperatively as the motor drives mechanical operation (e.g., motion) of the industrial automation components. The virtual representation may aid a user to determine adjustments that may improve the operation of the physical industrial automation components without needing to interact with (e.g., replace, adjust, or otherwise change industrial automation components) the physical industrial automation components. In any case, the mechanical load identification system may generate the mechanical load output that includes the digital twin, a visualization of the industrial automation component, a motion profile, or other representation of the industrial automation component using the mechanical parameters. In this way, the mechanical load identification system may be used to enable users to design and carry out desired tasks using industrial automation components by improving access to a model (e.g., the digital twin), recommending industrial automation components or subcomponents (e.g., via the BOM), and/or determining capabilities (e.g., throughput) of a physical industrial automation component.

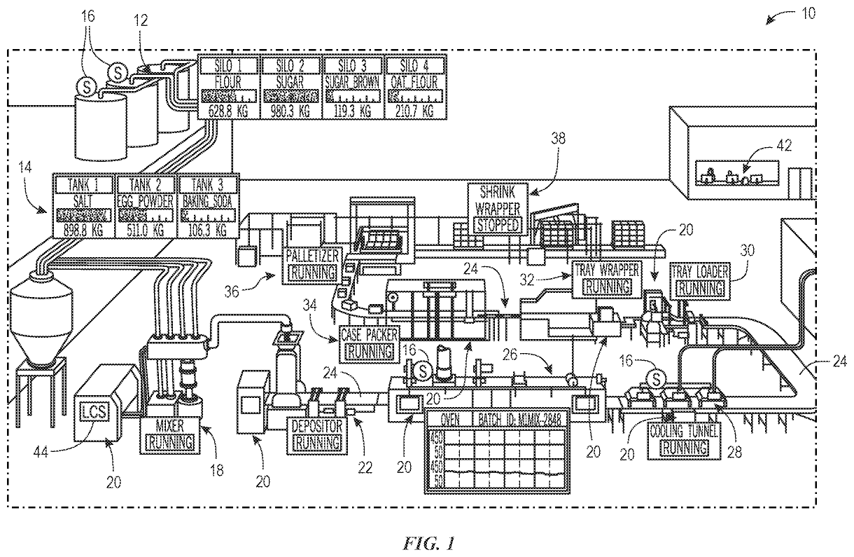

By way of introduction, FIG. 1 illustrates an example industrial automation system 10 employed by a food manufacturer. The present embodiments described herein may be implemented using the various devices illustrated in the industrial automation system 10 described below. However, it should be noted that although the example industrial automation system 10 of FIG. 1 is directed at a food manufacturer, the present embodiments described herein may be employed within any suitable industry, such as automotive, mining, hydrocarbon production, manufacturing, and the like. The following brief description of the example industrial automation system 10 employed by the food manufacturer is provided herein to help facilitate a more comprehensive understanding of how the embodiments described herein may be applied to industrial devices to significantly improve the operations of the respective industrial automation system. As such, the embodiments described herein should not be limited to be applied to the example depicted in FIG. 1.

Referring now to FIG. 1, the example industrial automation system 10 for a food manufacturer may include silos 12 and tanks 14. The silos 12 and the tanks 14 may store different types of raw material, such as grains, salt, yeast, sweeteners, flavoring agents, coloring agents, vitamins, minerals, and preservatives. In some embodiments, sensors 16 may be positioned within or around the silos 12, the tanks 14, or other suitable locations within the industrial automation system 10 to measure certain properties, such as temperature, mass, volume, pressure, humidity, and the like.

The raw materials may be provided to a mixer 18, which may mix the raw materials together according to a specified ratio. The mixer 18 and other machines in the industrial automation system 10 may employ certain industrial automation devices 20 to control the operations of the mixer 18 and other machines. The industrial automation devices 20 may include controllers, input/output (I/O) modules, motor control centers, motors, human machine interfaces (HMIs), operator interfaces, contactors, starters, sensors 16, actuators, conveyors, drives, relays, protection devices, switchgear, compressors, sensor, actuator, firewall, network switches (e.g., Ethernet switches, modular-managed, fixed-managed, service-router, industrial, unmanaged, etc.) and the like.

The mixer 18 may provide a mixed compound to a depositor 22, which may deposit a certain amount of the mixed compound onto conveyor 24. The depositor 22 may deposit the mixed compound on the conveyor 24 according to a shape and amount that may be specified to a control system for the depositor 22. The conveyor 24 may be any suitable conveyor system that transports items to various types of machinery across the industrial automation system 10. For example, the conveyor 24 may transport deposited material from the depositor 22 to an oven 26, which may bake the deposited material. The baked material may be transported to a cooling tunnel 28 to cool the baked material, such that the cooled material may be transported to a tray loader 30 via the conveyor 24. The tray loader 30 may include machinery that receives a certain amount of the cooled material for packaging. By way of example, the tray loader 30 may receive 25 ounces of the cooled material, which may correspond to an amount of cereal provided in a cereal box.

A tray wrapper 32 may receive a collected amount of cooled material from the tray loader 30 into a bag, which may be sealed. The tray wrapper 32 may receive the collected amount of cooled material in a bag and seal the bag using appropriate machinery. The conveyor 24 may transport the bagged material to case packer 34, which may package the bagged material into a box. The boxes may be transported to a palletizer 36, which may stack a certain number of boxes on a pallet that may be lifted using a forklift or the like. The stacked boxes may then be transported to a shrink wrapper 38, which may wrap the stacked boxes with shrink-wrap to keep the stacked boxes together while on the pallet. The shrink-wrapped boxes may then be transported to storage or the like via a forklift or other suitable transport vehicle.

To perform the operations of each of the devices in the example industrial automation system 10, the industrial automation devices 20 may provide power to the machinery used to perform certain tasks, provide protection to the machinery from electrical surges, prevent injuries from occurring with human operators in the industrial automation system 10, monitor the operations of the respective device, communicate data regarding the respective device to a supervisory control system 40, and the like. In some embodiments, each industrial automation device 20 or a group of industrial automation devices 20 may be controlled using a local control system 42. The local control system 42 may include receive data regarding the operation of the respective industrial automation device 20, other industrial automation devices 20, user inputs, and other suitable inputs to control the operations of the respective industrial automation device(s) 20.

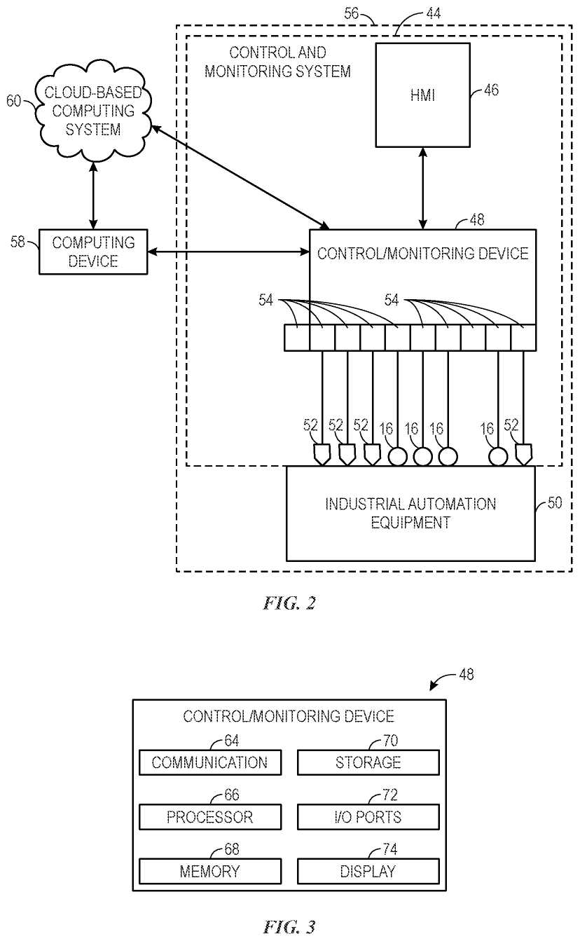

By way of example, FIG. 2 illustrates a diagrammatical representation of an exemplary local control system 42 that may be employed in any suitable industrial automation system 10, in accordance with embodiments presented herein. In FIG. 2, the local control system 42 is illustrated as including a human machine interface (HMI) 46 and a control/monitoring device 48 or automation controller adapted to interface with devices that may monitor and control various types of industrial automation component 50. By way of example, the industrial automation component 50 may include the mixer 18, the depositor 22, the conveyor 24, the oven 26, other pieces of machinery described in FIG. 1, or any other suitable equipment.

It should be noted that the HMI 46 and the control/monitoring device 48, in accordance with embodiments of the present techniques, may be facilitated by the use of certain network strategies. Indeed, any suitable industry standard network or network may be employed, such as DeviceNet, to enable data transfer. Such networks permit the exchange of data in accordance with a predefined protocol and may provide power for operation of networked elements.

As discussed above, the industrial automation component 50 may take many forms and include devices for accomplishing many different and varied purposes. For example, the industrial automation component 50 may include machinery used to perform various operations in a compressor station, an oil refinery, a batch operation for making food items, a mechanized assembly line, and so forth. Accordingly, the industrial automation component 50 may comprise a variety of operational components, such as electric motors, valves, actuators, temperature elements, pressure sensors, or a myriad of machinery or devices used for manufacturing, processing, material handling, and other applications.

Additionally, the industrial automation component 50 may include various types of equipment that may be used to perform the various operations that may be part of an industrial application. For instance, the industrial automation component 50 may include electrical equipment, hydraulic equipment, compressed air equipment, steam equipment, mechanical tools, protective equipment, refrigeration equipment, power lines, hydraulic lines, steam lines, and the like. Some example types of equipment may include mixers, machine conveyors, tanks, skids, specialized original equipment manufacturer machines, and the like. In addition to the equipment described above, the industrial automation component 50 may be made up of certain automation devices 20, which may include controllers, input/output (I/O) modules, motor control centers, motors, human machine interfaces (HMIs), operator interfaces, contactors, starters, sensors 16, actuators, drives, relays, protection devices, switchgear, compressors, firewall, network switches (e.g., Ethernet switches, modular-managed, fixed-managed, service-router, industrial, unmanaged, etc.), and the like.

In certain embodiments, one or more properties of the industrial automation component 50 may be monitored and controlled by certain equipment for regulating control variables used to operate the industrial automation component 50. For example, the sensors 16 may monitor various properties of the industrial automation component 50 and may provide data to the local control system 42, which may adjust operations of the industrial automation component 50, respectively. For example, the local control system 42, the control/monitoring device 48, or another suitable control system, may actuate one or more actuators 52.

In some cases, the industrial automation component 50 may be associated with devices used by other equipment. For instance, scanners, gauges, valves, flow meters, and the like may be disposed on industrial automation component 50. Here, the industrial automation component 50 may receive data from the associated devices and use the data to perform their respective operations more efficiently. For example, a controller (e.g., control/monitoring device 48) of a motor drive may receive data regarding a temperature of a connected motor and may adjust operations of the motor drive based on the data.

In certain embodiments, the industrial automation component 50 may include a communication component that enables the industrial automation equipment 50 to communicate data between each other and other devices. The communication component may include a network interface that may enable the industrial automation component 50 to communicate via various protocols such as Ethernet/IP®, ControlNet®, DeviceNet®, or any other industrial communication network protocol. Alternatively, the communication component may enable the industrial automation component 50 to communicate via various wired or wireless communication protocols, such as Wi-Fi, mobile telecommunications technology (e.g., 2G, 3G, 4G, 5G, LTE), Bluetooth®, near-field communications technology, and the like.

The sensors 16 may be any number of devices adapted to provide information regarding process conditions. The actuators 52 may include any number of devices adapted to perform a mechanical action in response to a signal from a controller (e.g., the control/monitoring device 48). The sensors 16 and actuators 52 may be utilized to operate the industrial automation component 50. Indeed, they may be utilized within process loops that are monitored and controlled by the control/monitoring device 48 and/or the HMI 46. Such a process loop may be activated based on process input data (e.g., input from a sensor 16) or direct operator input received through the HMI 46. As illustrated, the sensors 16 and actuators 52 are in communication with the control/monitoring device 48. Further, the sensors 16 and actuators 52 may be assigned a particular address in the control/monitoring device 48 and receive power from the control/monitoring device 48 or attached modules.

Input/output (I/O) modules 54 may be added or removed from the control and monitoring system 44 (e.g., control/monitoring system 44) via expansion slots, bays or other suitable mechanisms. In certain embodiments, the I/O modules 54 may be included to add functionality to the control/monitoring device 48, or to accommodate additional process features. For instance, the I/O modules 54 may communicate with new sensors 16 or actuators 52 added to monitor and control the industrial automation component 50. It should be noted that the I/O modules 54 may communicate directly to sensors 16 or actuators 52 through hardwired connections or may communicate through wired or wireless sensor networks, such as Hart or IOLink.

Generally, the I/O modules 54 serve as an electrical interface to the control/monitoring device 48 and may be located proximate or remote from the control/monitoring device 48, including remote network interfaces to associated systems. In such embodiments, data may be communicated with remote modules over a common communication link, or network, wherein modules on the network communicate via a standard communications protocol. Many industrial controllers can communicate via network technologies such as Ethernet (e.g., IEEE702.3, TCP/IP, UDP, Ethernet/IP, and so forth), ControlNet, DeviceNet or other network protocols (Foundation Fieldbus (H1 and Fast Ethernet) Modbus TCP, Profibus) and also communicate to higher level computing systems.

In the illustrated embodiment, several of the I/O modules 54 may transfer input and output signals between the control/monitoring device 48 and the industrial automation component 50. As illustrated, the sensors 16 and actuators 52 may communicate with the control/monitoring device 48 via one or more of the I/O modules 54 coupled to the control/monitoring device 48.

In certain embodiments, the control/monitoring system 44 (e.g., the HMI 46, the control/monitoring device 48, the sensors 16, the actuators 52, the I/O modules 54) and the industrial automation component 50 may make up an industrial automation application 56. The industrial automation application 56 may involve any type of industrial process or system used to manufacture, produce, process, or package various types of items. For example, the industrial applications 56 may include industries such as material handling, packaging industries, manufacturing, processing, batch processing, the example industrial automation system 10 of FIG. 1, and the like.

The control/monitoring device 48 may be communicatively coupled to a computing device 58 and a cloud-based computing system 60. In this network, input and output signals generated from the control/monitoring device 48 may be communicated between the computing device 58 and the cloud-based computing system 60. Although the control/monitoring device 48 may be capable of communicating with the computing device 58 and the cloud-based computing system 60, as mentioned above, in certain embodiments, the control/monitoring device 48 (e.g., local computing system 42) may perform certain operations and analysis without sending data to the computing device 58 or the cloud-based computing system 60.

FIG. 3 illustrates example components that may be part of the control/monitoring device 48 or any other suitable computing device that implement embodiments presented herein. For example, the control/monitoring device 48 may include a communication component 64 (e.g., communication circuitry), a processor 66, a memory 68, a storage 70, input/output (I/O) ports 72, a sensor 16 (e.g., an electronic data sensor, a temperature sensor, a vibration sensor, a camera), a display 74, and the like. The communication component 64 may be a wireless or wired communication component that may facilitate communication between the control/monitoring device 48, the local control system 42, and other communication capable devices.

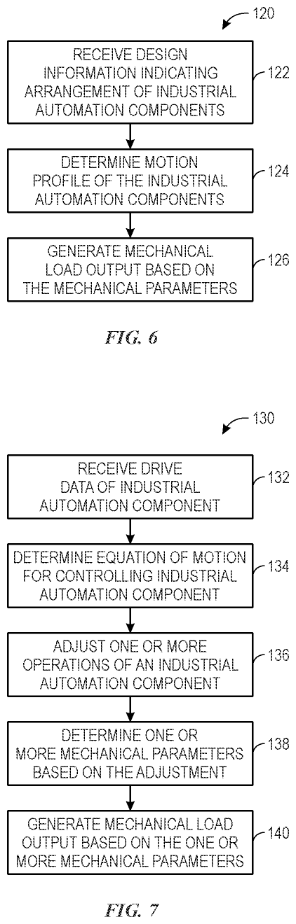

The processor 66 may be any type of computer processor or microprocessor capable of executing computer-executable code. The processor 66 may also include multiple processors that may perform the operations described below. The memory 68 and the storage 70 may be any suitable articles of manufacture that can serve as media to store processor-executable code, data, or the like. These articles of manufacture may represent computer-readable media (e.g., any suitable form of memory or storage) that may store the processor-executable code used by the processor 66 to perform the presently disclosed techniques. Generally, the processor 66 may execute software applications that include identifying anomalies in sensor data measured by the sensor 16, identifying a frequency corresponding to a change in the sensor data, determining a reduced set of sensor data, and generating constraints used to validate the sensor data, as discussed in more detail with respect to FIG. 6.

The memory 68 and the storage 70 may also be used to store the data, analysis of the data, the software applications, and the like. For example, the memory 68 and the storage 70 may store instructions associated with implementing different levels of processing for various operations. As another non-limiting example, the memory 68 and the storage 70 may store one or more previously acquired sensor data (e.g., by the sensor 16) or streamed sensor data. As another non-limiting example, the memory 68 and the storage 70 may store a constraint that represents a relationship between sensor data acquired by the sensor 16 and streamed sensor data from one or more additional sensors. The memory 68 and the storage 70 may represent non-transitory computer-readable media (e.g., any suitable form of memory or storage) that may store the processor-executable code used by the processor 66 to perform various techniques described herein. It should be noted that non-transitory merely indicates that the media is tangible and not a signal.

The I/O ports 72 may be interfaces that may couple to other peripheral components such as input devices (e.g., keyboard, mouse), sensors, input/output (I/O) modules, and the like. The I/O modules may enable the control/monitoring device 48 to communicate with the computing device 58, the control/monitoring device 48, the industrial automation component 50, or other devices in the industrial automation system via the I/O modules.

The display 74 may depict visualizations associated with software or executable code being processed by the processor 66. In one embodiment, the display 74 may be a touch display capable of receiving inputs (e.g., parameter data for operating the industrial automation component 50) from a user of the control/monitoring device 48, such as an indication indicating that the motion profile of an industrial automation component 50. As such, the display 74 may serve as a user interface to communicate with control/monitoring device 48. The display 74 may display a graphical user interface (GUI) for operating the control/monitoring device 48, for tracking the maintenance of the industrial automation component 50, and the like. The display 74 may be any suitable type of display, such as a liquid crystal display (LCD), plasma display, or an organic light emitting diode (OLED) display, for example. Additionally, in one embodiment, the display 74 may be provided in conjunction with a touch-sensitive mechanism (e.g., a touch screen) that may function as part of a control interface for the control/monitoring device 48 or for a number of pieces of industrial automation equipment in the industrial automation application 56, to control the general operations of the industrial automation application 56.

Although the components described above have been discussed with regard to the control/monitoring device 48 and the local control system 42, it should be noted that similar components may make up other computing devices described herein. Further, it should be noted that the listed components are provided as example components and the embodiments described herein are not to be limited to the components described with reference to FIG. 3. For example, the control/monitoring device 48 and the local control system 42 may include the communication component 64, the processor 66, the memory 68, the storage 70, the I/O ports 72, and the display 74. However, in general, the processor 66 of the control/monitoring device 48 may be capable of processing relatively more data than the processor 66 of the control/monitoring device 48. For example, the processor 66 of the control/monitoring device 48 may be capable of batch processing, while the processor 66 of the control/monitoring device 48 may be capable of processing streamed sensor data.

Keeping the foregoing in mind, in some embodiments, the memory 68 and/or storage 70 of the computing device 58 may include a software application that may be executed by the processor 66 and may be used to monitor, control, access, or view one of the industrial automation component 50. As such, the computing device 58 may communicatively couple to industrial automation component 50 or to a respective computing device of the industrial automation component 50 via a direct connection between the devices or via the cloud-based computing system 60. The software application may perform various functionalities, such as track statistics of the industrial automation component 50, store reasons for placing the industrial automation component 50 offline, determine reasons for placing the industrial automation component 50 offline, secure industrial automation component 50 that is offline, deny access to place an offline industrial automation component 50 back online until certain conditions are met, and so forth.

As another non-limiting example, and referring back to FIG. 2, in operation, the industrial automation application 56 may receive one or more process inputs to produce one or more process outputs. For example, the process inputs may include feedstock, electrical energy, fuel, parts, assemblies, sub-assemblies, operational parameters (e.g., sensor measurements), or any combination thereof. Additionally, the process outputs may include finished products, semi-finished products, assemblies, manufacturing products, by products, or any combination thereof.

To produce the processed outputs, the control/monitoring device 48 may output control signals to instruct industrial automation component 50 to perform one or more control actions. For example, the control/monitoring device 48 may instruct a motor (e.g., an automation device 20) to implement a control action to cause the motor to operate at a particular operating speed (e.g., a manipulated variable set point).

In some embodiments, the control/monitoring device 48 may determine the manipulated variable set points based at least in part on process data. As described above, the process data may be indicative of operation of the industrial automation device 20, the industrial automation component 50, the industrial automation application 56, and the like. As such, the process data may include operational parameters of the industrial automation device 20 and/or operational parameters of the industrial automation application 56. For example, the operational parameters may include any suitable type of measurement or control setting related to operating respective equipment, such as temperature, flow rate, electrical power, and the like.

Thus, the control/monitoring device 48 may receive process data from one or more of the industrial automation devices 20, the sensors 16, or the like. In some embodiments, the control/monitoring device 48 may determine an operational parameter and communicate a measurement signal indicating the operational parameter to the control/monitoring device 48 when the operational parameter is above a threshold (e.g., indicating an anomaly or a maintenance condition), in accordance with a frequency of the operational parameter occurring (e.g., as discussed in more detail with respect to FIG. 6), and the like. For example, a temperature sensor may measure a temperature of a motor (e.g., an automation device 20) and transmit a measurement signal indicating the measured temperature to the control/monitoring device 48. The control/monitoring device 48 may then analyze process data associated with the operation of the motor to monitor performance of an associated industrial automation application 56 (e.g., determine an expected operational state) and/or perform diagnostics on the industrial automation application 56 based on the measured temperature.

To facilitate controlling operation and/or performing other functions, the control/monitoring device 48 may include one or more controllers, such as one or more model predictive control (MPC) controllers, one or more proportional-integral-derivative (PID) controllers, one or more neural network controllers, one or more fuzzy logic controllers, and other suitable controllers.

In some embodiments, the supervisory control system 40 may provide centralized control over operation of the industrial automation application 56. For example, the supervisory control system 40 may enable centralized communication with a user (e.g., operator). To facilitate, the supervisory control system 40 may include the display 74 to provide information to the user. For example, the display 74 may present visual representations of information, such as process data, selected features, expected operational parameters, and/or relationships there between. Additionally, the supervisory control system 40 may include similar components as the control/monitoring device 48 described above in FIG. 3.

On the other hand, the control/monitoring device 48 may provide localized control over a portion of the industrial automation application 56. For example, in the depicted embodiment of FIG. 1, the local control system 42 that may be part of the mixer 18 may include the control/monitoring device 48, which may provide control over operation of a first automation device 20 that controls the mixer 18, while a second local control system 42 may provide control over operation of a second automation device 20 that controls the operation of the depositor 22.

In some embodiments, the local control system 42 may control operation of a portion of the industrial automation application 56 based at least in part on the control strategy determined by the supervisory control system 40. Additionally, the supervisory control system 40 may determine the control strategy based at least in part on process data determined by the local control system 42. Thus, to implement the control strategy, the supervisory control system 40 and the local control systems 42 may be communicatively coupled via a network, which may be any suitable type, such as an Ethernet/IP network, a ControlNet network, a DeviceNet network, a Data Highway Plus network, a Remote I/O network, a Foundation Fieldbus network, a Serial, DH-485 network, a SynchLink network, or any combination thereof.

As described herein, the mechanical load identification system utilizes design information and/or drive data of industrial automation components to generate a digital twin, a BOM, a motion profile, and the like, which may provide insights and predictions of a physical industrial automation component. As used herein, a “digital twin” refers to a model representative of a performance of the physical industrial automation component (e.g., via visualized on a graphical-user interface (GUI)) based on the mechanical parameters. The mechanical parameters of the industrial automation component may include a torque, acceleration inertia coefficients, viscous friction coefficients, Coriolis coefficients, other mechanical parameters that may be specific to a machine equipment (e.g., Coulomb and Stribeck terms). As used herein, a “bill of materials” or “BOM” refers to data or information that identifies one or more subcomponents and/or one or industrial automation components and/or the capabilities (e.g., throughput, output, load) of the industrial automation components that may aid a user in designing a system to perform an industrial process. As user herein, a “motion profile” refers to data or information indicating motion parameters of an industrial automation component or subcomponent based on the mechanical parameters of the industrial automation component. For example, the motion profile of a motor may indicate an equation of motion for the industrial automation component.

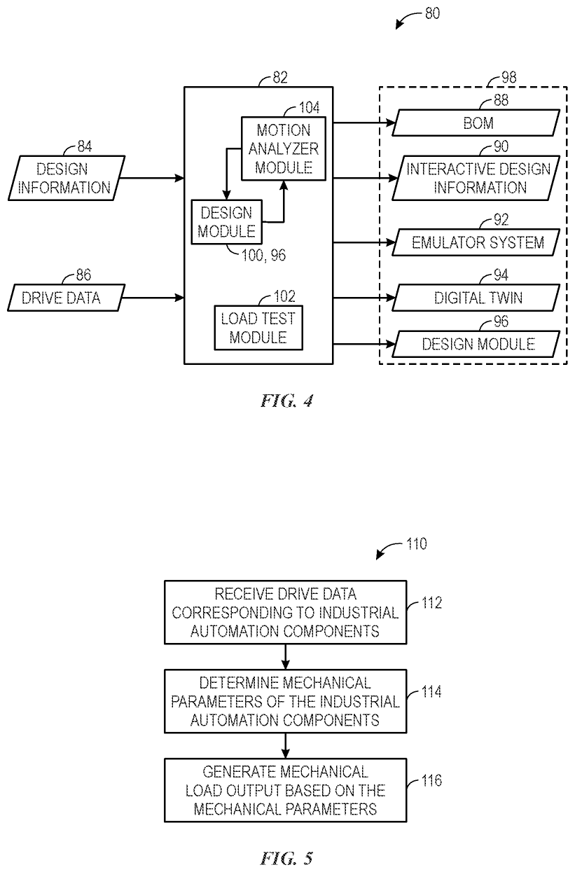

With the foregoing in mind, FIG. 4 is a block diagram 80 of a mechanical load identification system 82 used to perform the operations described herein. In some embodiments, the mechanical load identification system 82 may be a software application having instructions executable by a processor to generate the model used to control one or more industrial automation components of the industrial automation system 10 based on received process inputs (e.g., u(t)) and process outputs (e.g., y(t)) related to an industrial automation component 50, component, subcomponent(s), and the like. For example, the mechanical load identification system 82 may be implemented by the processor 66 of the control/monitoring device 48 and/or stored in the memory 68 of the control/monitoring device 48. In general, the mechanical load identification system 82 may include generally similar features at the control/monitoring device 48, such as a processor and a memory.

As illustrated, the mechanical load identification system 82 receives design information 84 and/or drive data 86 and outputs a BOM 88, interactive design information 90, an emulator system 92 (e.g., an emulation capable model), a digital twin 94, and a design module 96. While five outputs (e.g., the BOM 88, the interactive design information 90, the emulator system 92, the digital twin 94, and the design module 96) are shown, it should be noted that the mechanical load identification system 82 may generate any number of such outputs. As described in more detail herein, the mechanical load identification system 82 may output any combination of the BOM 88, the interactive design information 90, the emulator system 92, the digital twin 94, and the design module 96 as a mechanical load output 98. In some embodiments, the mechanical load output 98 may be a model used to control operation of the industrial automation system 10 (e.g., executed by the control/monitoring device 48 or other suitable computing device).

In some embodiments, the mechanical load output 98 may be an alert, notification, or otherwise communicate information (e.g., causing the display 74 to depict a graphical user interface (GUI)) indicating information related to industrial automation equipment. For example, the mechanical load output 98 may include the BOM 88. As such, the mechanical load output 98 may cause a display (e.g., the display 74) to depict the arrangement of industrial automation component 50 and/or a list of industrial automation component 50 on the display. In some embodiments, the mechanical load identification system 82 may use the digital twin 94 to generate the alert, notification, or communication of information associated with the mechanical load output 98. For example, the mechanical load identification system 82 may utilize the digital twin 94 cooperatively with a condition monitoring technique. Accordingly, the mechanical load identification system 82 may utilize the digital twin 94 to verify or determine whether a monitored condition corresponds to an unexpected condition (e.g., an anomaly or a condition indicating that the industrial automation component 50 should receive maintenance) or an expected condition (e.g., the industrial automation component 50 is operating correctly or otherwise within a threshold error range).

As described above, the BOM 88 includes data or information that identifies one or more subcomponents and/or one or industrial automation components and/or the capabilities (e.g., throughput, output, load) of the industrial automation components that may aid a user in designing a system to perform an industrial process. For example, the BOM 88 may include a listing and/or relative arrangement of industrial automation component 50 for performing a desired task. As such, the BOM 88 may include a recommendation of an industrial automation component 50 to provide a predetermined throughput of an industrial automation system 10. The interactive design information 90 is generally an interactive software model that may aid a user in visualizing an arrangement of one or more subcomponents and/or industrial automation component 50. The interactive design information 90 have any suitable format such as a “.stp” file, a “.demo3d” file, a “.3mf” file, a “.demo3d” file, and the like.

The emulator system 92 is generally a software component that emulates a load on a simulated drive. Emulator system 92 may provide real-time motion control behavior that may be simulated at the motion axis, motion module, or motion group level, with hardware components (e.g., the hardware components may be unconnected, partially connected, or completely connected). As such, the emulator system 92 may aid a user to program instructions (e.g., for a programmable logic controller (PLC)) and test the logic of the instructions, even without having access to a physical drive and motor connected to a controller. For example, the emulator system 92 may include a model or equation that describes a motor load from a frame of reference of the motor. By providing the emulator system 92, the mechanical load identification system 82 may help a user verify timing in the operation of industrial automation components 50, verify logic control in the industrial automation system 10, and program the industrial automation system 10 and one or more components.

As described herein, the digital twin 94 provides a model representative of a performance of the physical industrial automation component 50 or component. The digital twin 94 may facilitate condition monitoring of the industrial automation component 50, thereby enabling a user to determine mechanical parameters that may change as the industrial automation component 50 operations. For example, the digital twin 94 may aid a user in determining whether a spring constant or inertia of the industrial automation component 50 is decreasing (e.g., or increasing), thereby indicating whether the industrial automation component 50 is performing as expected or in an unexpected manner (e.g., indicating that the industrial automation component 50 should be replaced, repaired, or otherwise received maintenance). The design module 96 is a module that identifies, determines, or analyzes, the motion of the industrial automation component 50. For example, the design module 96 may present an arrangement and/or listing of the industrial automation component 50. In some embodiments, the design module 96 may operate in a concerted manner with a BOM. For example, the mechanical load identification system 82 may present the arrangement and output the BOM 88 associated with the arrangement. Further, the design module 96 may receive an input (e.g., a user input) indicating a change or adjustment to one or more industrial automation components 50 of the arrangement. In turn, the mechanical load identification system 82 and/or design module 96 may output an updated BOM 88 based on the input.

In general operation, the mechanical load identification system 82 may receive design information 84 and provide the design information 84 to a design module 100. In some embodiments, the design module 100 may be the design module 96 described above. For example, the mechanical load identification system 82 may receive drive data 86 and generate the design module 96 based on the drive data 86, as described in more detail with respect to FIG. 5. In some embodiments, the mechanical load identification system 82 may utilize a load test module 102 that may test an industrial automation component 50 to determine mechanical parameters that may be used to analyze the motion of the industrial automation component 50. In any case, the design module 100 may generate a mechanical load output 98 that includes a model (e.g., the digital twin 94) representing the industrial automation component 50, that could be used in emulator system 92, the digital twin 94, the interactive design information 90, or a combination thereof. In some embodiments, the design module 96 may provide these outputs (e.g., the emulator system 92, the digital twin 94, the interactive design information 90, or a combination thereof) to a motion analyzer 104. Once the motion analyzer 104 receives the model, the motion analyzer 104 may determine a motion profile for performing a particular task (e.g., based on user input). In turn, the motion analyzer 104 may determine a particular drive, motor, gearbox, or other equipment may accomplish the motion profile for a particular load. The motion analyzer 104 may be a module capable of determining an arrangement and/or a particular industrial automation component 50 to perform a desired task. For example, the motion analyzer 104 may receive input (e.g., user input) indicating a desired throughput of the industrial automation system 10. In turn, the motion analyzer 104 may output the BOM 88 to recommend industrial automation component 50 for performing the desired task.

In some embodiments, the mechanical load identification system 82 may utilize one or more modules to perform the operations described herein. As used herein, the term “module” may correspond to any suitable set of software instructions, code, or component that performs a particular task or set of tasks. In addition, the “module” may also refer to a hardware component designed to perform the particular task or the set of tasks.

As described above, the mechanical load identification system 82 may utilize drive data 86 to determine or generate models (e.g., the digital twin 94 and/or design module 96) representative of industrial automation component 50 for performing a desired task. FIG. 5 illustrates a flowchart of a method 110 for generating a model of a physical industrial automation component 50 using drive data 86. In general, the method 110 may be performed by a processor or suitable computer device capable of communicating with other components in an industrial automation system may perform the disclosed method 110 including, but not limited to, a cloud-based computing system, a computing device, and the like. In some embodiments, the steps of method 110 may be performed by the processor 66 of the control/monitoring device 48.

Referring now to FIG. 5, at block 112, the mechanical load identification system 82 may receive drive data associated with one or more industrial automation components, machines, and the like associated with the industrial automation system 10. As described herein, the drive data may include drive current or other data indicating a mechanical load (e.g., a force) provided by the physical industrial automation components. As such, the drive data may include a drive current corresponding to changes or adjustments in operation of a physical industrial automation component 50. As described in more detail in FIG. 7, the drive current may be used to determine the mechanical parameters of the model for the physical industrial automation component 50. In this way, the mechanical load identification system 82 may generate the mechanical load output 98, which may include a digital twin 94, from a physical device with little to no input from the user.

At block 114, the mechanical load identification system 82 may determine mechanical parameters corresponding to the one or more industrial automation component 50. For example, the mechanical parameters may include a moment of inertia of a load of the plurality of drives, a motor torque constant, or a combination thereof. In some embodiments, the mechanical load identification system 82 may access an equation of motion for the industrial automation component 50. In general, the equation of motion may include one or more terms (i.e., the mechanical parameters), which the mechanical load identification system 82 may determine by performing one or more tests. In general, to perform the tests, the mechanical load identification system 82 may adjust operation of the physical industrial automation components 50, monitor or otherwise measure a change in the drive data, and determine the mechanical parameters based on the drive data. Additional details relating to the tests are described in FIG. 7.

At block 116, the mechanical load identification system 82 may generate a mechanical load output 98 based on the one or more mechanical parameters. In general, the mechanical load output 98 may include a model. For example, the mechanical load output 98 may include the interactive design information 90, the emulator system 92, the digital twin 94, and the design module 96. In some embodiments, the mechanical load identification system 82 may use one of the mechanical load outputs 98 to generate a different mechanical load output 98. That is, the mechanical load identification system 82 may generate a first output (e.g., the digital twin 94) and use the first output to generate a second output (e.g., the emulator system 92 and/or the design module 96). For example, the mechanical load identification system 82 may generate the interactive design information 90 based on drive data 86. In turn, the mechanical load identification system 82 may utilize the interactive design information 90 to determine, for example, a BOM 88. The BOM 88 may include a list of particular industrial automation components 50 that perform the desired task to achieve a particular goal (e.g., throughput). In this way, the mechanical load identification system 82 may generate a model (e.g., the design module 96 and/or the digital twin 94) by interacting with a physical device (i.e., the industrial automation component 50) and/or otherwise enable a user to improve the performance of the industrial automation system 10.

As described above, the mechanical load identification system 82 may utilize design information 84 to generate models (e.g., the digital twin 94 and/or design module 96) representative of industrial automation component 50 for performing a desired task. FIG. 6 illustrates a flowchart of a method 120 for generating a model of a physical industrial automation component 50 using design information 84. In general, the method 120 may be performed by a processor or suitable computer device capable of communicating with other components in an industrial automation system may perform the disclosed method 120 including, but not limited to, a cloud-based computing system, a computing device, and the like. In some embodiments, the steps of method 120 may be performed by the processor 66 of the control/monitoring device 48.

Referring now to FIG. 6, at block 122, the mechanical load identification system 82 may receive design information 84 associated with one or more industrial automation components, equipment, machines, and the like, of industrial automation system 10. In general, the design information 84 may indicate physical parameters of the components, equipment, machines, and the like. For example, the design information 84 may include a computer-aided design (CAD) file or other documentation including information such as dimensions of one or more subcomponents of an industrial automation components 50 (e.g., a diameter of a wheel of a conveyor belt, interior or exterior dimensions of an oven, and the like), a material type of the component (e.g., a type of thermoplastics, metal, rubber, fabric and/or leather of the belt of the conveyor), operational parameters (e.g., input output parameters, correlations), and the like.

At block 124, the mechanical load identification system 82 may determine a motion profile that describes expected motions performed by the industrial automation component 50 based on the received design information. In general, the motion profile may indicate a type of motion performed by the one or more industrial automation components 50 represented by the design information. For example, the mechanical load identification system 82 may identify industrial automation components 50, determine a motor and/or an arrangement of the industrial automation components 50 relative to the motor. Then, the mechanical load identification system 82 may determine motion information related to industrial automation components 50. The motion information may indicate that the industrial automation component 50 undergoes linear motion, rotational motion, or both. Further, the motion may indicate an acceleration and/or velocity (e.g., angular or linear) capable of being producing by the industrial automation component 50. In some embodiments, the mechanical load identification system 82 may utilize component identification information, such as a serial number, that identifies a particular physical component. In turn, the mechanical load identification system 82 may determine physical parameters of the industrial automation component 50 (e.g., dimensions, mass, an amount of torque, or other parameters related to the mechanical performance of the industrial automation component 50). In any case, using the motion information and the design information, the mechanical load identification system 82 may access a suitable equation of motion related to the motion profile. Further, the mechanical load identification system 82 may determine mechanical parameters related to the motion profile. An example equation of motion is described herein at equation 1.

At block 126, mechanical load identification system 82 generates a model based on the motion profile and the design information. In some embodiments, the generated model may be further optimized via verification of the model over time, as generally described with respect to block 116 of FIG. 5. In this way, the mechanical load identification system 82 may generate a mechanical load output 98, such as the BOM 88, the interactive design information 90, the digital twin 94, or a combination thereof. As described above, a first output of the mechanical identification system 82 may be used to generate a second output by the control/monitoring system 44, the mechanical identification system 82, or other suitable processing system. For example, the digital twin 94 may be used to generate the emulator system 92, the design module 96, or a combination thereof using a software file indicating an arrangement of the industrial automation component 50 (i.e., the design information 84).

As described above, the mechanical load identification system 82 may perform one or more tests to determine mechanical parameters corresponding to a physical industrial automation equipment. FIG. 7 illustrates a flowchart of a method 130 for determining mechanical parameters of industrial automation component 50 and generating a mechanical load output 98 based on the mechanical parameters. In general, the method 130 may be performed by a processor or suitable computer device capable of communicating with other components in an industrial automation system may perform the disclosed method 130 including, but not limited to, a cloud-based computing system, a computing device, and the like. In some embodiments, the steps of method 130 may be performed by the processor 66 of the control/monitoring device 48.

At block 132, the mechanical load identification system 82 receives drive data 86 of the industrial automation component 50. For example, the mechanical load identification system 82 may measure, receive, or otherwise obtain drive current(s), voltage(s), frequency, and any known motor parameters (such as the motor torque constant) corresponding to operation of a drive.

At block 134, the mechanical load identification system 82 may determine or receive an equation of motion for controlling the industrial automation equipment. For example, the mechanical load identification system 82 may access reference data to determine an equation of motion that may represent operations performed by the industrial automation component 50. In some embodiments, the mechanical load identification system 82 may execute or perform one or more tests, as described herein, to determine one or more terms of the equation of motion. After determining the equation of motion, the mechanical load identification system 82, in some embodiments, may access reference data using the equation of motion and drive data 86. In turn, the mechanical load identification system 82 may identify the machine equipment of the industrial automation component 50, such as a type of the machine equipment (e.g., a motor), an amount of each machine equipment, and an arrangement of the machine equipment.

At block 136, the mechanical load identification system 82 may adjust one or more operations (e.g., mechanical operations) of the industrial automation component 50. In general, adjusting the one or more operations of the industrial automation component 50 may include operating the machine equipment at a constant velocity, acceleration, or other parameter, in accordance with one or more tests, as described in more detail below. At block 138, the mechanical load identification system 82 may determine one or more mechanical parameters based on the adjustment. To facilitate the discussion of block 134, block 136, and block 138, a non-limiting example is provided below.

As described above, the mechanical load identification system 82 may determine one or more mechanical parameters of an equation of motion. An example equation is shown below:

$${M}_{D} = {J}_{e q} ( θ ) \cdot \ddot{θ} + \frac{{dJ}_{e q} ( θ )}{d θ} \cdot {\dot{θ}}^{2} + {B}_{e q} ( θ ) \cdot \dot{θ} + {K}_{e q} ( θ ) \cdot θ + \sqrt{2 e} ( {T}_{b r k} - {T}_{C} ) {e}^{- {( \frac{ω}{{ω}_{St}} )}^{2}} \cdot \frac{ω}{{ω}_{St}} + {T}_{C} \cdot tanh ( \frac{ω}{{ω}_{Ct}} ) \qquad ( 1 )$$

Where M_{D} is an applied motor developed torque, J_{eq}(θ) is an equivalent inertia from the motor axis frame of reference,

$$\frac{{dJ}_{e q} ( θ )}{d θ}$$

is the Coriolis coefficient from the motor axis frame of reference, B_{eq}(θ) is the viscous friction coefficient from the motor axis frame of reference, K_{eq}(θ) is the elastic torque (e.g., spring constant torque) from the motor axis frame of reference, T_{brk} is the breakaway friction torque, T_{C} is the Coulomb friction torque, ω is the angular velocity, ω_{St} is the Stribeck angular velocity threshold, and ω_{St} is the Coulomb angular velocity threshold.

To determine the mechanical parameters (e.g., J_{eq}(θ),

$$\frac{{dJ}_{e q} ( θ )}{d θ} ,$$

B_{eq}(θ), K_{eq}(θ), and the like) the mechanical load identification system 82 may perform one or more tests to isolate the one or more mechanical parameters. As one non-limiting example, industrial automation component 50 may include a motor driving an armature that drives a load. The mechanical load identification system 82 may perform a first test to determine the K_{eq}(θ). The first test may include the mechanical load identification system 82 adjusting operation of the industrial automation component 50, such as by incrementing a position (e.g., rotating through degrees at a predetermined increment such as 1°, 2°, 3°, 5°, and so on) of a motor the industrial automation component 50 and measuring the torque or the industrial automation equipment. For example, the mechanical load identification system 82 may hold or maintain the industrial automation component 50 at rest at each the positions. Then, the mechanical load identification system 82 may measure a drive current or via a virtual torque sensor (VTS). Then, the mechanical load identification system 82 may determine the torque based on the applied current. From the motor axis frame of reference, this test will yield:

$${M}_{D} = {K}_{e q} ( θ ) \cdot θ \qquad ( 2 )$$

where K_{eq} is position dependent for a time varying system and may be fit using a sum of sines. For example, the inertia response may be measured using the drive current. Then, the measured inertia response may be converted to the frequency domain to identify the dominant sinusoidal terms. As such, the effective inertia terms may be determined by the sum of the sine functions. For time invariant systems, K_{eq} is a constant (i.e. not position dependent).

As another non-limiting example, the mechanical load identification system 82 may perform a second test (e.g., after the first test and/or using a known mechanical parameter) to determine additional mechanical parameters of equation 1, such as

$$\frac{{dJ}_{e q} ( θ )}{d θ}$$

and/or B_{eq}(θ). For example, the mechanical load identification system 82 may adjust operation of the industrial automation component 50 by running a motor of the industrial automation component 50 at constant velocities (e.g., maintaining a motion of the motor at the constant velocity). As described above, the mechanical load identification system 82 may Accordingly, equation 1 becomes:

$$\frac{{dJ}_{e q} ( θ )}{d θ} = \frac{\frac{M - {K}_{e q} ( θ ) \cdot {θ}_{2}}{{\dot{θ}}_{2}} - \frac{{M}_{{D}_{1}} - {K}_{e q} ( θ ) \cdot {θ}_{1}}{{\dot{θ}}_{1}}}{{\dot{θ}}_{2} - {\dot{θ}}_{1}} \qquad ( 3 )$$

$${B}_{e q} ( θ ) = \frac{{M}_{D} - {K}_{e q} ( θ ) \cdot θ - \frac{{dJ}_{eq} ( θ )}{d θ} \cdot {\dot{θ}}^{2}}{\dot{θ}} \qquad ( 4 )$$

It should be noted there may be other ways to solve for

$$\frac{{dJ}_{e q} ( θ )}{d θ}$$

and B_{eq}(θ), and equations (3) and (4) are non-limiting example equations.

As such, the mechanical load identification system 82 may determine

$$\frac{{dJ}_{e q} ( θ )}{d θ}$$

and/or B_{eq}(θ) using the constant velocity and K_{eq}(θ)·determine in the first test.

As another non-limiting example, the mechanical load identification system 82 may perform a third test (e.g., after the first test or after the second test) to determine additional mechanical parameters of equation 1, such as J_{eq}(θ). For example, the mechanical load identification system 82 may adjust operation of the industrial automation component 50 by running the motor of the industrial automation component 50 at a constant acceleration (e.g., maintaining a motion of the industrial automation component 50 at a constant acceleration). In such an embodiment, the mechanical load identification system 82 may determine J_{eq}(θ) using the mechanical parameters determined at the previous tests (e.g., the first test and/or the second test), In other methods, a physical test (e.g. constant acceleration test) may be omitted and use only results from previous test (e.g. integrate

$$\frac{{dJ}_{e q} ( θ )}{d θ}$$

with respect to θ), or based on input provided by a user. In some embodiments, the mechanical load identification system 82 may perform multiple tests at different constant velocities. It should be noted that running the test at two different velocities may aid a user to determine whether the Coriolis term exists (e.g., the system is time variant if the Coriolis term exists). Further, running the test at different velocities may reduce or substantially eliminate a damping term, thereby isolating the Coriolis term. In an embodiment where the tests are performed based on received design information 84, the mechanical load identification system may set the force acceleration, the stiffness and the gravity to zero and velocity to unity to determine the effective damping term. Then, the mechanical load identification system 82 may set the damping to zero and measure the inertia during the test. Then, the mechanical load identification system 82 may subtract the two runs to eliminate the Coriolis term. Follow the same procedure as in described with respect to the first test to obtain a sum of sines equation describing the effect damping term. However, if drive data 86 is used, the mechanical identification system 82 may perform the constant velocity test (e.g., running the test at two different velocities). In this way, the mechanical load identification system 82 may determine mechanical parameters used to model industrial automation component 50.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

While only certain features of the embodiments described herein have been illustrated and described, many modifications and changes will occur to those skilled in the art. It is, therefore, to be understood that the appended claims are intended to cover all such modifications and changes as fall within the true spirit of the embodiments described herein.

1. A method, comprising:
receiving, via one or more processors, design information indicating an arrangement of a plurality of industrial automation components, wherein the plurality of industrial automation components comprises a motor;
determining, via the one or more processors, an equation of motion representing a mechanical operation of the plurality of industrial automation components based on the arrangement of the plurality of industrial automation components;
determining, via the one or more processors, a plurality of mechanical parameters representing the mechanical operation of the plurality of industrial automation components based on the equation of motion;
generating, via the one or more processors, a model of the plurality of industrial automation components based on the plurality of mechanical parameters, wherein model represents one or more operations of a physical arrangement of the plurality of industrial automation components.

2. The method of claim 1, wherein the design information comprises a computer-aided design file.

3. The method of claim 1, wherein the plurality of mechanical parameters comprise an elastic torque of the plurality of the industrial automation components, a viscous friction coefficient, a Coriolis coefficient, an acceleration inertia coefficient, or a combination thereof.

4. The method of claim 1, wherein the model is representative of a load of the motor from a frame of reference of the motor.

5. The method of claim 4, wherein the equation of motion comprises:
$${M}_{D} = {J}_{e q} ( θ ) \cdot \ddot{θ} + \frac{{dJ}_{e q} ( θ )}{d θ} \cdot {\dot{θ}}^{2} + {B}_{e q} ( θ ) \cdot \dot{θ} + {K}_{e q} ( θ ) \cdot θ + \sqrt{2 e} ( {T}_{b r k} - {T}_{C} ) {e}^{- {( \frac{ω}{{ω}_{St}} )}^{2}} \cdot \frac{ω}{{ω}_{St}} + {T}_{c} \cdot tanh ( \frac{ω}{{ω}_{Ct}} ) ,$$
and wherein M_{D} is an applied motor developed torque, J_{eq}(θ) is an equivalent inertia from a frame of reference of an axis of the motor,
$$\frac{{dJ}_{e q} ( θ )}{d θ}$$
is the Coriolis coefficient, B_{eq}(θ) is a viscous friction coefficient, K_{eq}(θ) is an elastic torque, T_{brk} is the breakaway friction torque, T_{C} is a Coulomb friction torque, ω is the angular velocity, ω_{St} is a Stribeck angular velocity threshold, and ω_{St} is a Coulomb angular velocity threshold.

6. The method of claim 1, wherein the plurality of industrial automation components comprises a mechanical element driven by the motor.

7. The method of claim 1, wherein the model comprises a three-dimensional virtual representation of the plurality of industrial automation components.

8. The method of claim 1, wherein the model comprises a digital twin of the plurality of industrial automation components.

9. A method, comprising:
receiving, via one or more processors, drive data corresponding to a load provided by a motor to one or more industrial automation components;
adjusting, via the one or more processors, a mechanical operation of the one or more industrial automation components via the motor;
determining, via the one or more processors, a plurality of mechanical parameters of the one or more industrial automation components based on a change of the drive current resulting from the adjusted mechanical operation;
generating, via the one or more processors, a model representative of the one or more industrial automation components based on the plurality of mechanical parameters.

10. The method of claim 9, wherein adjusting the operation of the one or more industrial automation components comprises performing a plurality of tests to adjust the mechanical operation of the one or more industrial automation components; and
determining the plurality of mechanical parameters based on the plurality of tests.

11. The method of claim 10, wherein at least one test of the plurality of tests comprises maintaining a position of the plurality of the industrial automation components.

12. The method of claim 10, wherein at least one test of the plurality of tests comprises maintaining a constant velocity of the plurality of the industrial automation components.

13. The method of claim 10, wherein the drive data comprises drive current and a torque constant associated with the motor.

14. The method of claim 9, wherein the model comprises a digital twin correspond to the one or more industrial automation components.

15. The method of claim 9, wherein the model is representative of a load of the motor from a frame of reference of the motor.

16. A non-transitory computer-readable medium comprising computer-executable instructions that, when executed, are configured to cause a processor to perform operations comprising:
receiving drive current corresponding to a load provided to one or more of industrial automation components by a motor;
adjusting a mechanical operation of the one or more industrial automation components via the motor in accordance with a plurality of tests;
determining, via the one or more processors, a plurality of mechanical parameters of an equation of motion representing movement by the one or more industrial automation components with respect to the motor based on the plurality of tests; and
generating, via the one or more processors, a model representative of the equation of motion of the one or more industrial automation components based on the plurality of mechanical parameters.

17. The non-transitory computer-readable medium of claim 16, wherein the plurality of mechanical parameters comprise a spring constant torque of the one or more industrial automation components, a viscous friction coefficient, a Coriolis coefficient, an acceleration inertia coefficient, or a combination thereof.

18. The non-transitory computer-readable medium of claim 16, wherein a first test of the plurality of tests comprises maintaining a position of the plurality of the industrial automation components.

19. The non-transitory computer-readable medium of claim 18, wherein a second test of the plurality of tests comprises maintaining a constant velocity of the plurality of the industrial automation components.

20. The non-transitory computer-readable medium of claim 19, wherein a third test of the plurality of tests comprises maintaining a constant acceleration of the plurality of industrial automation components.
